(19) United States
(12) Patent Application Publication
(10) Pub. No.: US 2020/0243785 A1
(43) Pub. Date: Jul. 30, 2020

(54) THIN FILM PACKAGE STRUCTURE AND THIN FILM PACKAGE METHOD OF ORGANIC LIGHT EMITTING DIODE DISPLAY

(71) Applicant: WUHAN CHINA STAR OPTOELECTRONICS SEMICONDUCTOR DISPLAY TECHNOLOGY CO., LTD., Wuhan, Hubei (CN)

(72) Inventor: Xuebing YIN, Wuhan, Hubei (CN)

(21) Appl. No.: 16/475,681

(22) PCT Filed: Apr. 15, 2019
(86) PCT No.: PCT/CN2019/082601

§ 371 Date: Jul. 3, 2019

(30) Foreign Application Priority Data
Jan. 29, 2019 (CN) 201910087433.8

(51) Int. Cl. H01L 51/50; H01L 51/52

(52) U.S. Cl. CPC H01L 51/502; H01L 51/5237; H01L 51/506

(57) ABSTRACT

The present invention provides a thin film package structure of an organic light emitting diode (OLED) display, comprising an inorganic layer and an organic layer, wherein the inorganic layer and the organic layer are formed on a substrate, and the inorganic layer and the organic layer are alternately disposed, wherein the inorganic layer comprises an inorganic polymer doped with metal nanoparticles.

### BACKGROUND OF INVENTION

### Field of Invention

The present invention relates to a field of display, and in particular to a thin film package structure and a thin film package method of an organic light emitting diode display.

### Description of Prior Art

At present, organic materials for an organic light emitting diode display (OLED) display are highly susceptible to water and oxygen in the air, resulting in device failure. Therefore, it is necessary to package the OLED device and require a water oxygen transmission rate of less than 10-6 g/m2d. A common conventional OLED package is a glass package. As the display technology moves toward flexibility, flexible display technology requires a thin film package which has a basic structure of organic-inorganic multilayered package. Inorganic materials are brittle by their nature, and cracks and even crack propagation are prone to occur during bending, resulting in failure of the package layer and loss of water and oxygen resistance.

In order to improve the bending property of the inorganic layer, it is generally required to form the inorganic layer into a special shape of a zigzag or a wave shape to relieve stress, but there is still a risk of tendency to create or even exacerbate local stress concentration at chamfers of these special shapes, which are more likely to cause cracks.

Therefore, in the conventional thin film package technology of an organic light emitting diode display, there are still brittleness problems that stress concentration or even crack is easily generated in the inorganic layer of the thin film package structure, and improvement is urgently required.

### SUMMARY OF INVENTION

The present invention relates to a thin film package structure and a thin film package method of an organic light emitting diode display to solve the brittleness problems that stress concentration or even crack is easily generated in the inorganic layer of the thin film package structure.

To solve the above problems, technical solutions provided by the present invention are as follows:

According to a thin film package structure of an organic light emitting diode display according to the present invention, the thin film package structure of the organic light emitting diode display includes an inorganic layer and an organic layer, wherein the inorganic layer and the organic layer are formed on a substrate, and the inorganic layer and the organic layer are alternately disposed, wherein the inorganic layer comprises an inorganic polymer doped with metal nanoparticles.

According to a preferred embodiment provided by the present invention, the inorganic polymer of the inorganic layer comprises one or more selected from a group consisting of aluminum oxide, silicon nitride, silicon oxide, zirconium oxide, silicon carbide, titanium oxide, cerium oxide, and magnesium oxide.

According to a preferred embodiment provided by the present invention, the metal nanoparticles comprise one or more selected from a group consisting of copper, aluminum, barium, magnesium, platinum, silver, and lead.

According to a preferred embodiment provided by the present invention, the inorganic layer and the organic layer each comprise at least one layer and are alternately disposed.

According to a preferred embodiment provided by the present invention, the inorganic layer comprises a first inorganic layer and a second inorganic layer, and the organic layer has only one layer.

The present invention further provides a thin film package structure of an organic light emitting diode display including an inorganic layer and an organic layer formed on a substrate, wherein the inorganic layer comprises an inorganic polymer doped with metal nanoparticles

According to a preferred embodiment provided by the present invention, the inorganic polymer of the inorganic layer comprises one or more selected from a group consisting of aluminum oxide, silicon nitride, silicon oxide, zirconium oxide, silicon carbide, titanium oxide, cerium oxide, and magnesium oxide.

According to a preferred embodiment provided by the present invention, the metal nanoparticles comprise one or more selected from a group consisting of copper, aluminum, barium, magnesium, platinum, silver, and lead.

According to a preferred embodiment provided by the present invention, the inorganic layer and the organic layer each comprise at least one layer and are alternately disposed.

According to a preferred embodiment provided by the present invention, the inorganic layer comprises a first inorganic layer and a second inorganic layer, and the organic layer has only one layer.

The present invention also provides a film package method, including the following steps: S10, providing a substrate; S20, forming a first inorganic layer on the substrate, the first inorganic layer doped with metal nanoparticles; S30, thereafter, forming an organic layer on the substrate; and S40, forming a second inorganic layer on the substrate after the above steps are completed, the second inorganic layer doped with metal nanoparticles.

According to a preferred embodiment provided by the present invention, in the step S20 and the step S40, the first inorganic layer and the second inorganic layer are formed by co-deposition, co-sputtering or pulse laser evaporation, and in the step S30, the organic layer is formed by inkjet printing or coating.

According to a preferred embodiment provided by the present invention, the first inorganic layer has a thickness of 1000 nm, and the organic layer has a thickness of 1-10 um.

According to a preferred embodiment provided by the present invention, the organic layer is made of one or more materials of polyimide, epoxy, and silicone.

According to a preferred embodiment provided by the present invention, the metal nanoparticles are present in amount of 5 vol % to 10 vol % in the inorganic layer.

According to a preferred embodiment provided by the present invention, the substrate is a rigid substrate or a flexible substrate.

According to a preferred embodiment provided by the present invention, the rigid substrate is a glass substrate or a quartz substrate, and the flexible substrate is a resin substrate.

According to a preferred embodiment provided by the present invention, the flexible substrate is a polyimide substrate, a polyamide substrate, a polycarbonate substrate, or a polyethersulfone substrate.

Compared with the prior art, the inorganic layer of the thin film package structure of the organic light emitting diode display according to the present invention is doped with metal nanoparticles, which can prevent cracks propagation, effectively enhance the strength and tenacity of a matrix, and effectively achieve a purpose of improving brittleness of the inorganic materials in the thin film package structure. Also, a good thermal conductivity of the metal nanoparticles can effectively improve the heat dissipation performance of the organic light emitting diode display.

### BRIEF DESCRIPTION OF DRAWINGS

In order to more clearly illustrate the embodiments or the technical solutions of the existing art, the drawings illustrating the embodiments or the existing art will be briefly described below. Obviously, the drawings in the following description merely illustrate some embodiments of the present invention. Other drawings may also be obtained by those skilled in the art according to these figures without paying creative work.

FIG. 1 is a structural diagram of a thin film package of an organic light emitting diode display according to an embodiment of the present invention.

FIG. 2 is a first process diagram of a method of fabricating a thin film package of an organic light emitting diode display according to an embodiment of the present invention.

FIG. 3 is a second process diagram of a method of fabricating a thin film package of an organic light emitting diode display according to an embodiment of the present invention.

FIG. 4 is a third process diagram of a method of fabricating a thin film package of an organic light emitting diode display according to an embodiment of the present invention.

FIG. 5 is a first schematic flowchart of a method of package a thin film of an organic light emitting diode display according to an embodiment of the present invention.

### DETAILED DESCRIPTION OF PREFERRED EMBODIMENTS

Please refer to the figures in the drawings, in which, like numbers refer to like elements throughout the description of the figures. Hereinafter, the present invention will be described in further detail with reference to examples. It is to be understood, however, that these examples are for illustrative purposes only and are not intended to limit the scope of the present invention.

In the description of the present invention, it is to be understood that the terms “center”, “lateral”, “upper”, “lower”, “left”, “right”, “vertical”, “horizontal”, “top”, “bottom”, “inside”, “outside” and the like are based on the orientation or positional relationship shown in the drawings, and is merely for the convenience of describing the present invention and simplifying the description, and does not indicate or imply that the indicated devices or components must to be in particular orientations, or constructed and operated in a particular orientation, and thus are not to be construed as limiting the invention. Furthermore, the terms “first”, “second”, etc. in the specification and claims of the present invention and the above figures are used to distinguish similar objects, and are not necessarily used to describe a specific order or prioritization. It should be understood that the objects so described are interchangeable when it is appropriate. Moreover, the terms “including” and “having” and any variations thereof are intended to cover a non-exclusive “inclusion”. In the description of the present application, the meaning of “a plurality” is two or more unless clearly and specifically defined otherwise.

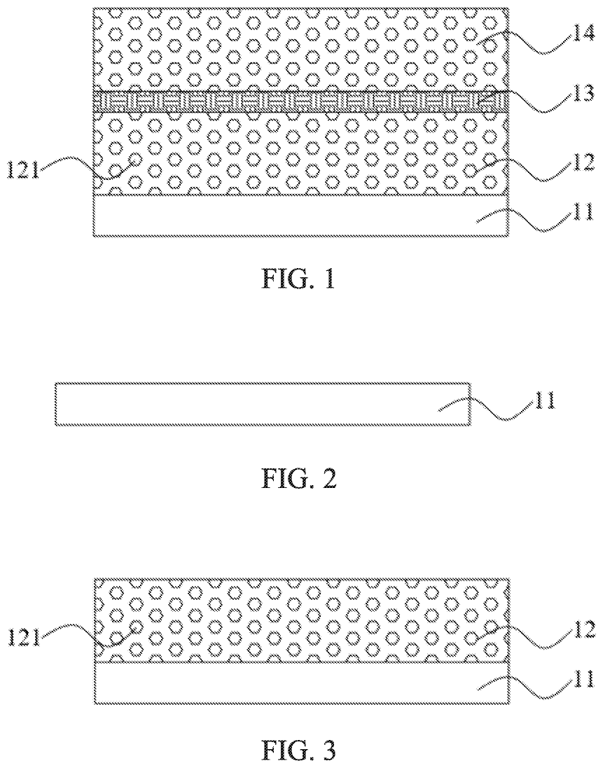

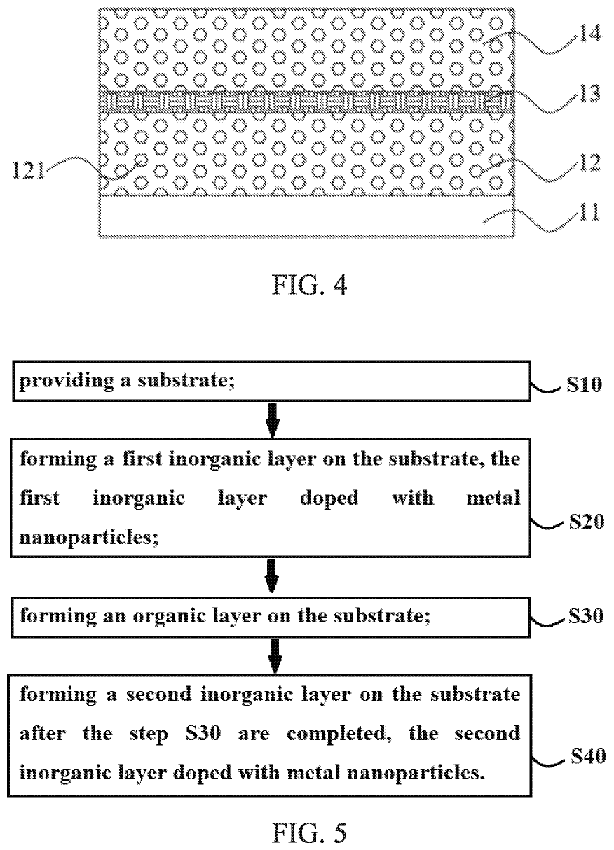

The present invention provides a thin film package structure and a thin film package method of an organic light emitting diode display, which are specifically illustrated in FIGS. 1-5.

Referring to FIG. 1, a thin film package structure diagram of an organic light emitting diode display is shown. The element 11 refers to a substrate, the element 12 refers to a first inorganic layer, the element 121 refers to a metal nanoparticle, the element 13 refers to an organic layer, and the element 14 refers to a second inorganic layer.

The present invention provides a thin film package structure of an organic light emitting diode display. The thin film package structure of the organic light emitting diode display includes inorganic layers (12 and 14) and an organic layer 13, wherein the inorganic layers (12 and 14) and the organic layer 13 are formed on the substrate 11, and the inorganic layers (12 and 14) are made of an inorganic polymer doped with metal nanoparticles 121.

According to a preferred embodiment provided by the present invention, the inorganic polymer of the inorganic layer comprises one or more selected from a group consisting of aluminum oxide, silicon nitride, silicon oxide, zirconium oxide, silicon carbide, titanium oxide, cerium oxide, and magnesium oxide. The inorganic layer may be formed on the substrate of the organic light emitting diode display by means of co-sputtering, thermal evaporation, or laser pulse plating (PLD).

According to a preferred embodiment provided by the present invention, materials of the metal nanoparticles 121 has good ductility and thermal conductivity, and may include one or more selected from a group consisting of copper, aluminum, barium, magnesium, platinum, silver or lead.

According to a preferred embodiment provided by the present invention, the inorganic layer and the organic layer 13 each include at least one layer and are alternately disposed, wherein the inorganic layer includes a first inorganic layer 12 and a second inorganic layer 14, while the organic Layer 13 has only one layer. The first inorganic layer 12 is disposed on the substrate, the organic layer 13 is disposed on the first inorganic layer 12, and the second inorganic layer 14 is disposed on the organic layer 13.

Referring to FIG. 2 to FIG. 5, the present invention further provides a thin film package method of an organic light emitting diode display, including the following steps: S10, providing a substrate 11; S20, forming an first inorganic layer 12 on the substrate 11; S30, thereafter, forming an organic layer 13 on the substrate 11; and S40, after completing the step S30, forming a second inorganic layer 14 on the substrate 11. The substrate 11 is a rigid substrate or a flexible substrate, preferably a flexible substrate, to realize a display function. The rigid substrate may be selected from a glass substrate or a quartz substrate. The flexible substrate is a resin substrate which may be selected from an organic substrate such as a polyimide substrate, a polyamide substrate, a polycarbonate substrate, or a polyether sulfone substrate.

According to a preferred embodiment provided by the present invention, in the step S20 and the step S40, the first inorganic layer 12 and the second inorganic layer 14 are formed by co-deposition, co-sputtering or pulse laser evaporation, and in the step S30, the organic layer is formed by inkjet printing or coating.

According to a preferred embodiment provided by the present invention, the first inorganic layer 12 has a thickness of 1000 nm, and the organic layer 13 has a thickness of 1-10 um, which serves to planarize. A thickness of the second inorganic layer 14 is equal to the thickness of the first inorganic layer 12.

According to a preferred embodiment provided by the present invention, the organic layer 13 is made of one or more materials of polyimide, epoxy, and silicone materials. The organic layer 13 can be processed and produced by low temperature heat curing and ultraviolet curing.

According to a preferred embodiment provided by the present invention, the metal nanoparticles 121 are present in amount of 5 vol % to 10 vol % in the inorganic layer 13.

The thin film package structure and the thin film package method of the organic light emitting diode display provided by the embodiments of the present invention are described in detail. The principles and implementations of the present invention are described in the specific embodiments. The description of the above embodiments is only used to help understand the technical solutions and the core ideas of the present invention. While the invention has been described by way of example and in terms of the preferred embodiments, it is to be understood that the invention is not limited to the disclosed embodiments. To the contrary, it is intended to cover various modifications and similar arrangements. Therefore, the scope of the appended claims should be accorded the broadest interpretation so as to encompass all such modifications and similar arrangements.

What is claimed is:

1. A thin film package structure of an organic light emitting diode (OLED) display, comprising an inorganic layer and an organic layer, wherein the inorganic layer and the organic layer are formed on a substrate, and the inorganic layer and the organic layer are alternately disposed, wherein the inorganic layer comprises an inorganic polymer doped with metal nanoparticles.

2. The thin film package structure of the organic light emitting diode display according to claim 1, wherein the inorganic polymer of the inorganic layer comprises one or more selected from a group consisting of aluminum oxide, silicon nitride, silicon oxide, zirconium oxide, silicon carbide, titanium oxide, cerium oxide, and magnesium oxide.

3. The thin film package structure of the organic light emitting diode display according to claim 1, wherein the metal nanoparticles comprise one or more selected from a group consisting of copper, aluminum, barium, magnesium, platinum, silver, and lead.

4. The thin film package structure of the organic light emitting diode display according to claim 1, wherein the inorganic layer and the organic layer each comprise at least one layer and are alternately disposed.

5. The thin film package structure of the organic light emitting diode display according to claim 4, wherein the inorganic layer comprises a first inorganic layer and a second inorganic layer, and the organic layer has only one layer.

6. A thin film package structure of the organic light emitting diode display, comprising an inorganic layer and an organic layer formed on a substrate, wherein the inorganic layer comprises an inorganic polymer doped with metal nanoparticles.

7. The thin film package structure of the organic light emitting diode display according to claim 6, wherein the inorganic polymer of the inorganic layer comprises one or more selected from a group consisting of aluminum oxide, silicon nitride, silicon oxide, zirconium oxide, silicon carbide, titanium oxide, cerium oxide, and magnesium oxide.

8. The thin film package structure of the organic light emitting diode display according to claim 6, wherein the metal nanoparticles comprise one or more selected from a group consisting of copper, aluminum, barium, magnesium, platinum, silver, and lead.

9. The thin film package structure of the organic light emitting diode display according to claim 6, wherein the inorganic layer and the organic layer each comprise at least one layer and are alternately disposed.

10. The thin film package structure of the organic light emitting diode display according to claim 9, wherein the inorganic layer comprises a first inorganic layer and a second inorganic layer, and the organic layer has only one layer.

11. A thin film package method for an organic light emitting diode display, comprising the following steps:
S10, providing a substrate;
S20, forming a first inorganic layer on the substrate, the first inorganic layer doped with metal nanoparticles;
S30, thereafter, forming an organic layer on the substrate; and
S40, forming a second inorganic layer on the substrate after the above steps are completed, the second inorganic layer doped with metal nanoparticles.

12. The thin film package method of the organic light emitting diode display according to claim 11, wherein in the step S20 and the step S40, the first inorganic layer and the second inorganic layer are formed by co-deposition, co-sputtering or pulse laser evaporation, and in the step S30, the organic layer is formed by inkjet printing or coating.

13. The thin film package method of the organic light emitting diode display according to claim 12, wherein the first inorganic layer has a thickness of 1000 nm, and the organic layer has a thickness of 1-10 um.

14. The thin film package method of the organic light emitting diode display according to claim 13, wherein the organic layer is made of one or more materials of polyimide, epoxy, and silicone.

15. The thin film package method of the organic light emitting diode display according to claim 14, wherein the metal nanoparticles are present in amount of 5 vol % to 10 vol % in the inorganic layer.

16. The thin film package method of the organic light emitting diode display according to claim 11, wherein the substrate is a rigid substrate or a flexible substrate.

17. The thin film package method of the organic light emitting diode display according to claim 16, wherein the rigid substrate is a glass substrate or a quartz substrate, and the flexible substrate is a resin substrate.

18. The thin film package method of the organic light emitting diode display according to claim 17, wherein the flexible substrate is a polyimide substrate, a polyamide substrate, a polycarbonate substrate, or a polyethersulfone substrate.
